(19) United States
(12) Patent Application Publication
(10) Pub. No.: US 2008/0136411 A1
(43) Pub. Date: Jun. 12, 2008

(54) MAGNETIC RESONANCE IMAGING APPARATUS AND MAGNETIC RESONANCE IMAGING METHOD

(76) Inventor: Mitsuharu Miyoshi, Tokyo (JP)

Correspondence Address: Patrick W. Rasche;Armstrong Teasdale LLP, Suite 2600, One Metropolitan Square, St. Louis, MO, 63102, US

(21) Appl. No.: 11/951,028

(22) Filed: Dec. 5, 2007

(30) Foreign Application Priority Data
Dec. 7, 2006 (JP) 2006-330959

(51) Int. Cl. G01R 33/483

(52) U.S. Cl. 324/309

(57) ABSTRACT

With the objective of generating an imaging area including fluid with desired image quality at a subject and enhancing image quality, a first inversion recovery pulse is transmitted so as to invert spins in a second subject region which includes a first subject region used as the imaging area and is broader than the first subject region, before execution of a pulse sequence corresponding to an FSE method at every TR in an imaging sequence. After the execution of the pulse sequence corresponding to the FSE method, a second refocus pulse is transmitted so as to cause spins in a third subject region including the first subject region and wider than the first subject region to reconverge. A fast recovery pulse is transmitted to selectively recover spins in the first subject region. Thereafter, a second inversion recovery pulse is transmitted so as to invert the spins in the second subject region.

### BACKGROUND OF THE INVENTION

The present invention relates to a magnetic resonance imaging (MRI) apparatus and a magnetic resonance imaging method. The present invention relates particularly to a magnetic resonance imaging apparatus and a magnetic resonance imaging method, which execute a scan for repeatedly executing, every time of repetition (TR: repetition time), an imaging sequence including a pulse sequence for sequentially transmitting an excitation pulse corresponding to an RF (Radio Frequency) pulse whose flip angle is 90°, and a plurality of refocus pulses each corresponding to an RF pulse whose flip angle is 180°, to a subject including fluid, so as to correspond to a fast spin echo (FSE) method in an imaging space formed with a static magnetic field, thereby obtaining magnetic resonance signals generated in an imaging area including the fluid at the subject, and generate images about the imaging area, based on the magnetic resonance signals obtained by executing the scan.

A magnetic resonance imaging apparatus has been used in various fields directed to medical applications, industrial applications and the like.

The magnetic resonance imaging apparatus repeatedly executes, every repetition time, an imaging sequence for applying RF pulses corresponding to electromagnetic waves to an imaging area to be photographed at a subject in a static magnetic field space to excite spins of proton in the imaging area by a nuclear magnetic resonance (NMR) phenomenon and obtaining magnetic resonance (MR) signals generated by the excited spins, thereby executing scans about the imaging area. The magnetic resonance signals obtained by the execution of the scans are used as raw data and thereby images about the imaging area are generated.

The magnetic resonance imaging apparatus executes a scan about an imaging area in accordance with, for example, an imaging sequence based on the fast spin echo method.

In addition to the above, there has been proposed a method for transmitting an inversion recovery pulse for inverting spins in an imaging area, based on an IR (Inversion Recovery) method before execution of a pulse sequence corresponding to a fast spin echo method in an imaging sequence and executing the pulse sequence based on the fast spin echo method after the elapse of an inversion time (TI) for recovering longitudinal magnetization by longitudinal relaxation of the spins (refer to, for example, a patent document 1).

In the magnetic resonance imaging apparatus, angiography called “MRA (MR angiography)” has been carried out to photograph or image an imaging area including fluid such as blood flowing through a subject. In the MRA, there is known an imaging method using a time of flight (TOF) effect, a phase contrast (PC) effect or the like. In the MRA as well, an FBI (Fresh Blood Imaging) method has been proposed as an imaging method which makes no use of a contract agent (refer to, for example, a patent document 2).

In the present FBI method, images about an imaging area through which fluid such as blood flows are generated during diastole and cardiac systole respectively. Here, a scan is carried out using an imaging sequence to which, for example, a three-dimensional fast spin echo method is applied, thereby to generate images. Then, an MRA image about a subject region is generated based on the value of the difference between these plural images. Here, a signal intensity arising from the arteries becomes low because the bloodstream velocity in arteries is fast during cardiac systole, and the signal intensity arising from the arteries becomes high because the bloodstream velocity in arteries is slow during diastole. Therefore, the MRA image generated based on the difference value as described above becomes high in contrast.

[Patent Document 1] Japanese Unexamined Patent Publication No. 2003-38456.

[Patent Document 2] Japanese Unexamined Patent Publication No. 2000-5144.

When, however, the refocus pulses are sequentially transmitted after execution of the pulse sequence corresponding to the fast spin echo method in the above imaging sequence, the refocus pulses are selectively transmitted with respect to their corresponding slices in a manner similar to the excitation pulse transmitted in the pulse sequence based on the fast spin echo method, thus resulting in the fact that each spin of a flow running through the neighborhood of each of the slices is not refocused. Upon transmission of the inversion recovery pulse as above, the slice is selected and defined as the imaging area in a manner similar to the excitation pulse in the pulse sequence based on the fast spin echo method. Therefore, no inversion recovery pulse is applied to each flow running from the outside to inside of the slice.

Therefore, there may be cases where when the imaging area including the fluid is photographed at the subject, defective conditions such as the difficulty of generating each image having desired image quality, etc. are encountered.

Since an STIR (short TI inversion recovery) method is applied to the fast spin echo method for the purpose of fat control in the above-described FBI method, magnetic resonance signals can be acquired only once per three heart beats to perfectly recover longitudinal magnetization about the blood in which a T1 relaxation time is 1200 ms or so. Therefore, there may be cases in which imaging cannot be performed efficiently and a difficulty occurs in an increase in imaging efficiency.

### SUMMARY OF THE INVENTION

It is desirable that the problems described previously are solved.

There is provided a magnetic resonance imaging apparatus of one aspect of the invention, comprising a scan section for repeatedly executing, every repetition time, an imaging sequence including a pulse sequence for sequentially transmitting an excitation pulse and a plurality of first refocus pulses to a subject including fluid, so as to correspond to a fast spin echo method in an imaging space formed with a static magnetic field, thereby obtaining magnetic resonance signals generated in a first subject region including the fluid at the subject every repetition time, and an image generation section for generating images about the first subject region, based on the magnetic resonance signals obtained by executing the imaging sequence by the scan section, wherein before execution of the pulse sequence corresponding to the fast spin echo method at every time of repetition in the imaging sequence, the scan section transmits a first inversion recovery pulse so as to invert spins in a second subject region which includes the first subject region and is broader than the first subject region, at the subject.

Preferably, before execution of the pulse sequence corresponding to the fast spin echo method at every repetition time in the imaging sequence and after the transmission of the first inversion recovery pulse, the scan section transmits a first killer pulse so as to generate a gradient magnetic field for causing lateral magnetization of the spins inverted by the first inversion recovery pulse to disappear.

Preferably, upon executing the pulse sequence corresponding to the fast spin echo method, the scan section transmits the excitation pulse so as to selectively excite the spins in the first subject region.

Preferably, upon executing the pulse sequence corresponding to the fast spin echo method, the scan section transmits the plurality of first refocus pulses so as to cause spins in a third subject region including the first subject region to reconverge at the subject after the transmission of the excitation pulse.

Preferably, after execution of the pulse sequence corresponding to the fast spin echo method at every repetition time in the imaging sequence, the scan section transmits a second refocus pulse so as to cause the spins in the third subject region to reconverge, transmits a fast recovery pulse so as to selectively recover the spins in the first subject region included in the third subject region at which the second refocus pulse is transmitted, at the subject, and thereafter transmits a second inversion recovery pulse so as to invert the spins in the second subject region including the first subject region at which the fast recovery pulse is transmitted, at the subject.

Preferably, after the transmission of the fast recovery pulse at every repetition time in the imaging sequence and before the transmission of the second inversion recovery pulse, the scan section transmits a second killer pulse so as to generate a gradient magnetic field for causing lateral magnetization of the spins at which the fast recovery pulse is transmitted, to disappear, and after the transmission of the second inversion recovery pulse, transmits a third killer pulse so as to generate a gradient magnetic field for causing lateral magnetization of the spins inverted by the second inversion recovery pulse to disappear.

Preferably, the scan section transmits the first inversion recovery pulse in such a manner that each spin faced in a static magnetic field direction formed with a static magnetic field at the subject is rotated by 180°, transmits the excitation pulse in such a manner that the spin at which the first inversion recovery pulse is transmitted, is rotated by 90° about a second direction orthogonal to the static magnetic field direction and a first direction orthogonal to the static magnetic field direction, transmits the plurality of first refocus pulses, transmits the second refocus pulse, transmits the fast recovery pulse in such a manner that each spin at which the second refocus pulse is transmitted, is rotated by −90° about the second direction, and transmits the second inversion recovery pulse in such a manner that each spin at which the fast recovery pulse is transmitted, is rotated by −180°.

Preferably, the scan section transmits the first refocus pulses and the second refocus pulse in such a manner that each spin excited by the excitation pulse is rotated about the first direction.

Preferably, the scan section executes a preparation sequence for transmitting preparation pulses before execution of the imaging sequence so as to change a signal intensity of each magnetic resonance signal obtained by the imaging sequence according to the velocity of the fluid flowing through the subject.

Preferably, the scan section executes the imaging sequence in sync with cardiac motion of the subject.

In order to attain the above object, there is provided a magnetic resonance imaging method of the invention, comprising the steps of repeatedly executing, every repetition time, an imaging sequence including a pulse sequence for sequentially transmitting an excitation pulse and a plurality of first refocus pulses to a subject including fluid, so as to correspond to a fast spin echo method in an imaging space formed with a static magnetic field, thereby obtaining magnetic resonance signals generated in a first subject region including the fluid at the subject every repetition time; thereafter generating images about the first subject region, based on the magnetic resonance signals obtained by executing the imaging sequence; and before execution of the pulse sequence corresponding to the fast spin echo method at every time of repetition in the imaging sequence, transmitting a first inversion recovery pulse so as to invert spins in a second subject region which includes the first subject region and is broader than the first subject region, at the subject.

Preferably, before execution of the pulse sequence corresponding to the fast spin echo method at every repetition time in the imaging sequence and after the transmission of the first inversion recovery pulse, a first killer pulse is transmitted so as to generate a gradient magnetic field for causing lateral magnetization of the spins inverted by the first inversion recovery pulse to disappear.

Preferably, upon executing the pulse sequence corresponding to the fast spin echo method, the excitation pulse is transmitted so as to selectively excite the spins in the first subject region.

Preferably, upon executing the pulse sequence corresponding to the fast spin echo method, the plurality of first refocus pulses are transmitted so as to cause spins in a third subject region including the first subject region to reconverge at the subject after the transmission of the excitation pulse.

Preferably, after execution of the pulse sequence corresponding to the fast spin echo method at every repetition time in the imaging sequence, a second refocus pulse is transmitted so as to cause the spins in the third subject region to reconverge, a fast recovery pulse is transmitted so as to selectively recover the spins in the first subject region included in the third subject region at which the second refocus pulse is transmitted, at the subject, and thereafter a second inversion recovery pulse is transmitted so as to invert the spins in the second subject region including the first subject region at which the fast recovery pulse is transmitted, at the subject.

Preferably, after the transmission of the fast recovery pulse at every repetition time in the imaging sequence and before the transmission of the second inversion recovery pulse, a second killer pulse is transmitted so as to generate a gradient magnetic field for causing lateral magnetization of the spins at which the fast recovery pulse is transmitted, to disappear, and after the transmission of the second inversion recovery pulse, a third killer pulse is transmitted so as to generate a gradient magnetic field for causing lateral magnetization of the spins inverted by the second inversion recovery pulse to disappear.

Preferably, the first inversion recovery pulse is transmitted in such a manner that each spin faced in a static magnetic field direction formed with a static magnetic field at the subject is rotated by 180°, the excitation pulse is transmitted in such a manner that the spin at which the first inversion recovery pulse is transmitted, is rotated by 90° about a second direction orthogonal to the static magnetic field direction and a first direction orthogonal to the static magnetic field direction, the plurality of first refocus pulses are transmitted, the second refocus pulse is transmitted, the fast recovery pulse is transmitted in such a manner that each spin at which the second refocus pulse is transmitted, is rotated by −90° about the second direction, and the second inversion recovery pulse is transmitted in such a manner that each spin at which the fast recovery pulse is transmitted, is rotated by −180°.

Preferably, the first refocus pulses and the second refocus pulse are transmitted in such a manner that each spin excited by the excitation pulse is rotated about the first direction.

Preferably, a preparation sequence for transmitting preparation pulses is executed before execution of the imaging sequence so as to change a signal intensity of each magnetic resonance signal obtained by the imaging sequence according to the velocity of the fluid flowing through the subject.

Preferably, the imaging sequence is carried out in sync with cardiac motion of the subject.

According to the invention, there can be provided a magnetic resonance imaging apparatus and a magnetic resonance imaging method capable of easily improving image quality and enhancing imaging efficiency.

Further objects and advantages of the present invention will be apparent from the following description of the preferred embodiments of the invention as illustrated in the accompanying drawings.

### BRIEF DESCRIPTION OF THE DRAWINGS

FIG. 1 is a block diagram showing a construction of a magnetic resonance imaging apparatus 1 illustrative of a first embodiment according to the invention.

FIG. 2 is a flowchart showing operation at the execution of a scan on an imaging area of a subject SU in the first embodiment according to the invention.

FIG. 3 is a pulse sequence diagram showing an imaging sequence IS including a pulse sequence corresponding to a fast spin echo method in the first embodiment according to the invention.

FIG. 4 is a diagram typically showing an area slice-selected upon transmitting an excitation pulse RF1i and a fast recovery pulse FR and an area slice-selected upon transmitting RF pulses other than the excitation pulse RF1i and the fast recovery pulse FR at the imaging sequence IS employed in the first embodiment according to the invention.

FIG. 5 is a flowchart showing operation at the execution of a scan on an imaging area of a subject SU in the second embodiment according to the invention.

FIG. 6 is a pulse sequence diagram showing a preparation sequence PS employed in the second embodiment according to the invention.

FIG. 7 is a vector diagram showing the behaviors of spins of a subject SU when the preparation sequence PS is carried out in the second embodiment according to the invention.

### DETAILED DESCRIPTION OF THE INVENTION

### First Embodiment

A first embodiment according to the invention will be explained.

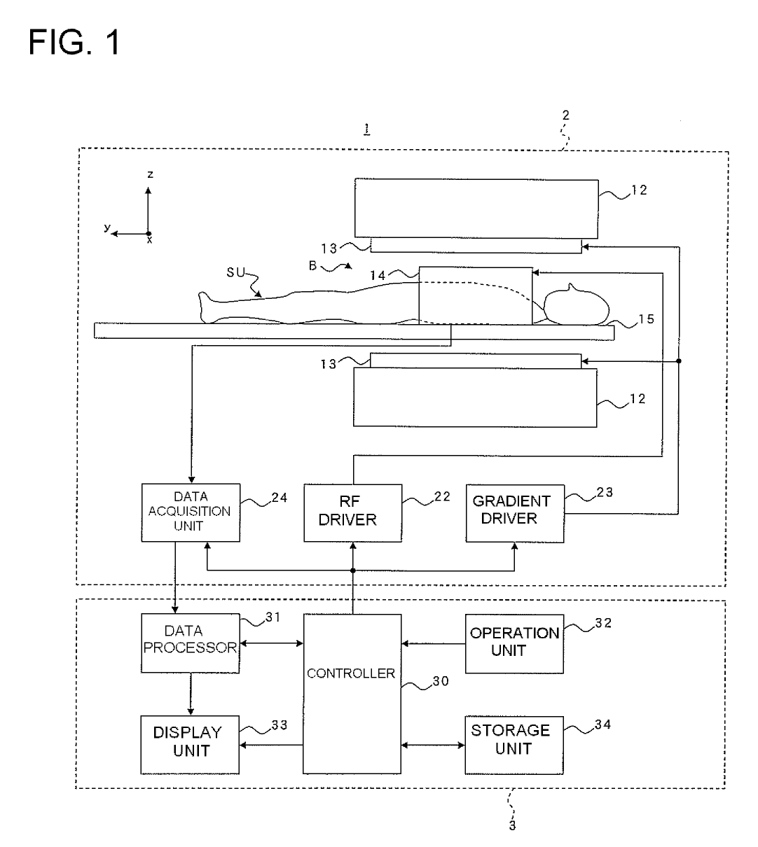

(Apparatus construction) FIG. 1 is a block diagram showing a construction of a magnetic resonance imaging apparatus 1 illustrative of the first embodiment according to the invention.

As shown in FIG. 1, the magnetic resonance imaging apparatus 1 of the present embodiment has a scan section 2 and an operation console section 3.

The scan section 2 will be described.

As shown in FIG. 1, the scan section 2 has a static magnetic field magnet unit 12, a gradient coil unit 13, an RF coil unit or part 14, a cradle 15, an RF driver 22, a gradient driver 23 and a data acquisition unit 24. Here, the scan section 2 executes an imaging sequence IS for transmitting an RF pulse to a subject SU so as to excite spins in a subject SU within an imaging space B formed with a static magnetic field and transmitting a gradient pulse to the subject SU to which the RF pulse has been transmitted, thereby obtaining each magnetic resonance signal generated in the subject SU as imaging data.

In the present embodiment, the scan section 2 executes the imaging sequence IS including a pulse sequence for sequentially transmitting an excitation pulse and a plurality of first refocus pulses to the subject including fluid, repeatedly every repetition time TR in the imaging space B formed with the static magnetic field so as to correspond to a fast spin echo method, thereby executing a scan. Thus, the scan section 2 obtains magnetic resonance signals generated in an imaging area including fluid such as blood at the subject as imaging data every repetition time TR.

Although described later in detail, the scan section 2 transmits a first inversion recovery pulse so as to invert spins in a second subject region which includes a first subject region corresponding to an imaging area to be photographed at the subject and which is wider than the first subject region before the pulse sequence corresponding to the fast spin echo method is executed at the repetition time TR in the imaging sequence IS.

Upon executing the pulse sequence corresponding to the fast spin echo method, an excitation pulse is transmitted so as to selectively excite the spins in the first subject region, and a plurality of first refocus pulses are transmitted so as to allow spins of a third subject region including the first subject region subjected to the transmission of the excitation pulse at the subject to reconverge.

After the execution of the pulse sequence corresponding to the fast spin echo method every repetition time TR in the imaging sequence IS, a second refocus pulse is transmitted to allow the spins of the third subject region to reconverge in a manner similar to the plurality of first refocus pulses. A fast recovery pulse is transmitted so as to selectively restore the spins in the first subject region contained in the third subject region subjected to the transmission of the second refocus pulse at the subject. Thereafter, a second inversion recovery pulse is transmitted so as to invert the spins of the second subject region that includes the first subject region subjected to the transmission of the fast recovery pulse and is wider than the first subject region at the subject.

Respective constituent elements of the scan section 2 will be explained sequentially.

The static magnetic field magnet unit 12 comprises, for example, a superconductive magnet (not shown) and forms a static magnetic field in the imaging space B in which the subject SU is accommodated or held. Here, the static magnetic field magnet unit 12 forms the static magnetic field so as to extend along a body-axis direction (z direction) of the subject SU placed on the cradle 15. Incidentally, the static magnetic field magnet unit 12 may be constituted of a pair of permanent magnets.

The gradient coil unit 13 forms a gradient magnetic field in the imaging space B formed with the static magnetic field and applies or adds spatial position information to the magnetic resonance signal received by the RF coil unit 14. Here, the gradient coil unit 13 comprises three systems set so as to correspond to three-axis directions of a z direction extending along a static magnetic field direction and an x direction and a y direction orthogonal to one another with respect to the z direction. These transmit gradient pulses in a frequency encode direction, a phase encode direction and a slice selection direction according to imaging conditions respectively thereby to form gradient magnetic fields. Described specifically, the gradient coil unit 13 applies the gradient magnetic field in the slice selection direction of the subject SU and selects a slice of the subject SU excited by transmission of an RF pulse by the RF coil unit 14. The gradient coil unit 13 applies the gradient magnetic field in the phase encode direction of the subject SU and phase-encodes a magnetic resonance signal from the slice excited by the RF pulse. And the gradient coil unit 13 applies the gradient magnetic field in the frequency encode direction of the subject SU and frequency-encodes the magnetic resonance signal from the slice excited by the RF pulse.

As shown in FIG. 1, the RF coil unit 14 is disposed so as to surround the subject SU. The RF coil unit 14 transmits an RF pulse corresponding to an electromagnetic wave to the subject SU within the imaging space B formed with the static magnetic field by the static magnetic field magnet unit 12 to form a high frequency magnetic field, thereby exciting the spins of proton in the subject SU. The RF coil unit 14 receives an electromagnetic wave generated from the excited proton in the subject SU as a magnetic resonance signal.

The cradle 15 has a base or table that places the subject SU thereon. A cradle section 26 moves between the inside and outside of the imaging space B, based on a control signal supplied from a controller 30.

The RF driver 22 drives the RF coil unit 14 to transmit an RF pulse to within the imaging space B, thereby forming a high frequency magnetic field therein. The RF driver 22 modulates a high frequency signal sent from an RF oscillator to a pulse having predetermined timing and predetermined envelope using a gate modulator on the basis of the control signal outputted from the controller 30. Thereafter, the RF driver 22 allows an RF power amplifier to amplify the pulse modulated by the gate modulator and outputs the same to the RF coil unit 14, and allows the RF coil unit 14 to transmit an RF pulse.

The gradient driver 23 applies a gradient pulse to the gradient coil unit 13 based on the control signal outputted from the controller 30 to drive the gradient coil unit 13, thereby to generate a gradient magnetic field within the imaging space B formed with the static magnetic field. The gradient driver 23 has a three-system drive circuit (not shown) in association with the three-system gradient coil unit 13.

The data acquisition unit 24 acquires each magnetic resonance signal received by the RF coil unit 14 based on the control signal outputted from the controller 30. Here, the data acquisition unit 24 phase-detects the magnetic resonance signal received by the RF coil unit 14 using a phase detector with the output of the RF oscillator of the RF driver 22 as a reference signal. Thereafter, the data acquisition unit 24 converts the magnetic resonance signal corresponding to the analog signal into a digital signal by using an A/D converter and outputs it therefrom.

The operation console section 3 will be explained.

As shown in FIG. 1, the operation console section 3 has the controller 30, a data processor 31, an operation unit 32, a display or display unit 33 and a storage unit 34.

Respective constituent elements of the operation console section 3 will be described sequentially.

The controller 30 has a computer and a memory that stores programs that allow the computer to execute predetermined data processing, and controls respective parts. Here, the controller 30 inputs operation data sent from the operation unit 32 and outputs the control signal to the RF driver 22, gradient driver 23 and data acquisition unit 24 respectively, based on the operation data inputted from the operation unit 32, thereby executing a predetermined scan. Along with it, the controller 30 outputs control signals to the data processor 31, display unit 33 and storage unit 34 to perform control on the respective parts.

The data processor 31 has a computer and a memory that stores programs that execute predetermined data processing using the computer. The data processor 31 executes data processing, based on the control signal supplied from the controller 30. Here, the data processor 31 uses the magnetic resonance signal obtained, as imaging data, by executing an imaging sequence by the scan section 2 as raw data and generates images about the subject SU. Then, the data processor 31 outputs each generated image to the display unit 33. Described specifically, the magnetic resonance signals each sampled every repetition time so as to correspond to a k space are inversely Fourier-transformed to reconstruct the images.

The operation unit 32 is constituted of an operation device such as a keyboard, a pointing device or the like. The operation unit 32 inputs operation data from an operator and outputs the same to the controller 30.

The display unit 33 is constituted of a display device such as a CRT and displays each image on its display screen, based on the control signal outputted from the controller 30. For example, the display unit 33 displays images about input items corresponding to the operation data inputted to the operation unit 32 by the operator on the display screen in plural form. Further, the display unit 33 receives data about each image of the subject SU generated based on the magnetic resonance signal from the subject SU from the data processor 31 and displays the image on the display screen. In the present embodiment, the display unit 33 displays a transmission sensitivity distribution generated by a transmission sensitivity distribution generator 132 on the screen. The display unit 33 displays an actual scan image corrected by an image correcting unit or corrector 133.

The storage unit 34 comprises a memory and stores various data therein. In the storage unit 34, the stored data are accessed by the controller 30 as needed.

(Operation) The operation of executing a scan on the imaging area including fluid at the subject SU by the magnetic resonance imaging apparatus 1 illustrative of the embodiment according to the invention will be explained below.

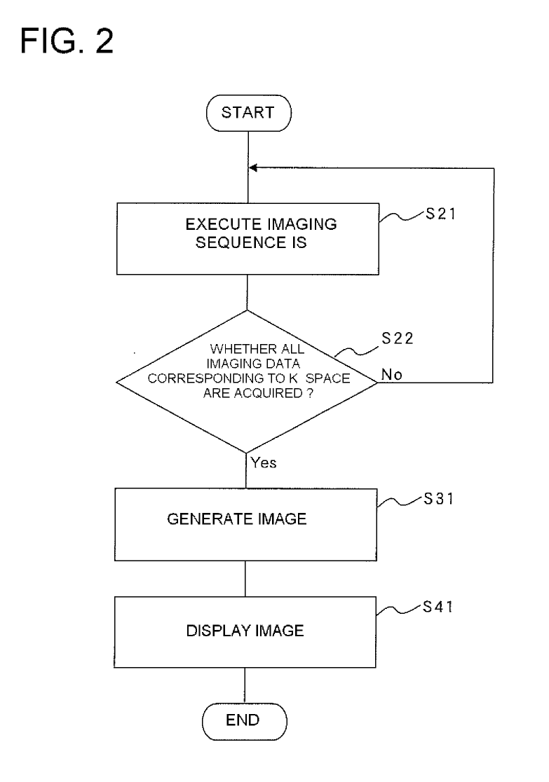

FIG. 2 is a flowchart showing operation at the execution of the scan on the imaging area of the subject SU in the first embodiment according to the invention.

As shown in FIG. 2, an imaging sequence IS is first executed (S21).

Here, the scan section 2 executes the imaging sequence IS so as to include a pulse sequence corresponding to a fast spin echo method.

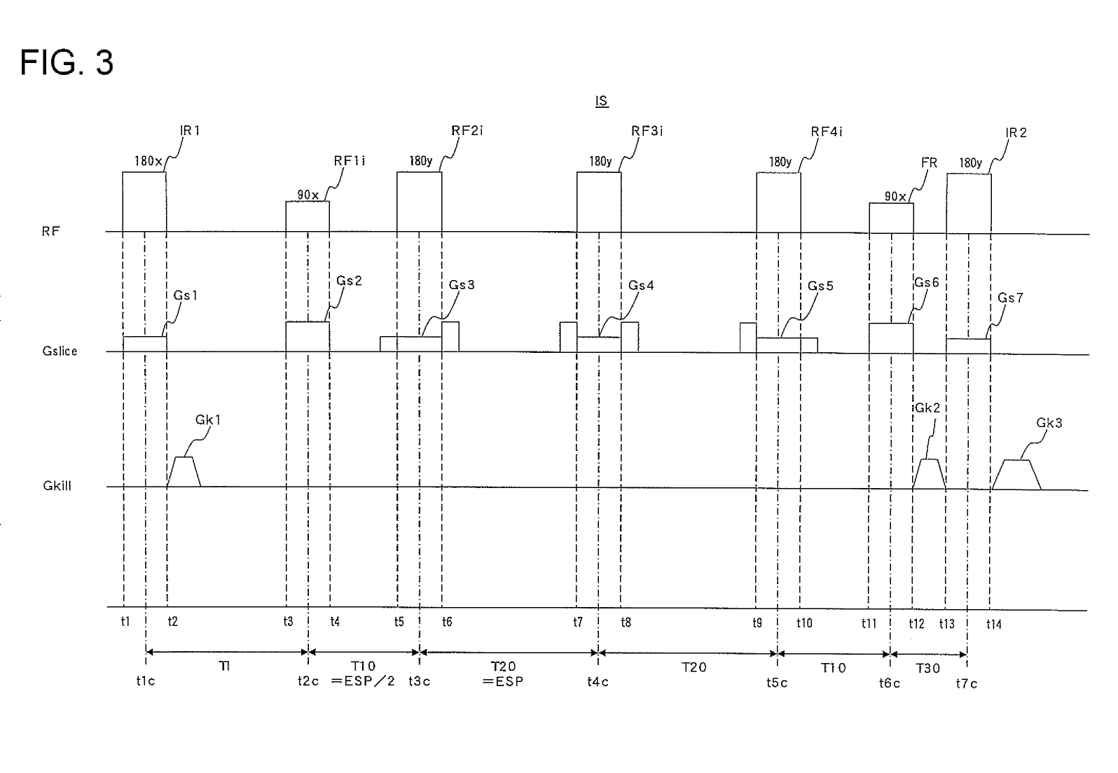

FIG. 3 is a pulse sequence diagram showing the imaging sequence IS including the pulse sequence corresponding to the fast spin echo method in the first embodiment according to the invention.

In FIG. 3, RF indicates a time base on which RF pulses are transmitted, Gslice indicates a time base on which gradient pulses are transmitted in a slice selection direction, and Gkill indicates a time base on which killer pulses area transmitted. At their RF, Gslice and Gkill, the horizontal axis indicates a time t, and the vertical axis indicates a pulse intensity, respectively. Here, Gkill is the time base on which the gradient pulses are transmitted and is a time base in at least one of a slice selection direction, a phase encode direction and a frequency encode direction. Incidentally, since the gradient pulses transmitted in the phase encode direction and the frequency encode direction (readout direction) are used to correspond or adapt to the known fast spin echo method, their description is omitted.

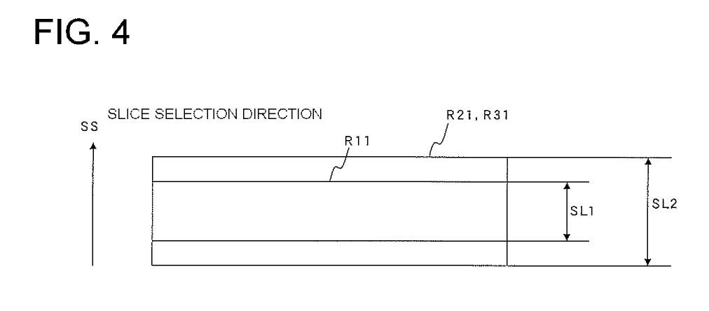

FIG. 4 is a diagram typically showing an area slice-selected upon transmitting an excitation pulse RF1i and a fast recovery pulse FR and an area slice-selected upon transmitting RF pulses other than the excitation pulse RF1i and the fast recovery pulse FR in the imaging sequence IS employed in the first embodiment according to the invention.

Upon execution of the imaging sequence IS in the present embodiment, as shown in FIGS. 3 and 4, a slice selection is performed so as to invert spins of a second subject region R21 which includes a first subject region R11 and broader than the first subject region R11 at a subject before the pulse sequence corresponding to the fast spin echo method is executed at every repetition time TR in the imaging sequence IS. The scan section 2 transmits a first inversion recovery pulse IR1.

Upon executing the pulse sequence corresponding to the fast spin echo method in the imaging sequence IS, as shown in FIGS. 3 and 4, the corresponding slice is selected such that the spins of the first subject region R11 are selectively excited, and the scan section 2 transmits an excitation pulse RF1i. Along with it, the corresponding slice is selected so as to cause spins of a third subject region R31 including the first subject region R11 with the excitation pulse RF1i transmitted thereat to reconverge at the subject, and the scan section 2 transmits a plurality of first refocus pulses RF2i and RF3i. Here, as shown in FIGS. 3 and 4, the corresponding slice is selected in such a manner that the third subject region R31 becomes the same area or region as the second subject region R21, and the scan section 2 transmits a plurality of first refocus pulses RF2i and RF3i. The scan section 2 executes the pulse sequence to set an echo train length (ETL) to 2 and adapt to a three-dimensional fast spin echo method, for example.

After the execution of the pulse sequence corresponding to the fast spin echo at every repetition time TR in the imaging sequence IS, as shown in FIGS. 3 and 4, the corresponding slice is selected so as to cause the spins of the third subject region R31 which includes the first subject region R11 done with the pulse sequence corresponding to the fast spin echo method and is broader than the first subject region R11 to reconverge at the subject, and the scan section 2 transmits a second refocus pulse RF4i. Here, as shown in FIGS. 3 and 4 in a manner similar to the above, the scan section 2 transmits the pulse in such a manner that the third subject region R31 becomes the same area as the second subject region R21.

The corresponding slice is selected so as to selectively restore the spins in the first subject region R11 contained in the third subject region R11 with the second refocus pulse RF4i transmitted thereto, and the scan section 2 transmits a fast recovery pulse FR. Thereafter, the corresponding slice is selected so as to invert the spins of the second subject region R21 which includes the first subject region R11 with the fast recovery pulse FR transmitted thereto and is broader than the first subject region R11 at the subject, and the scan section 2 transmits a second inversion recovery pulse IR2.

Here, before execution of the pulse sequence corresponding to the fast spin echo method at every repetition time TR in the imaging sequence IS and after the transmission of the first inversion recovery pulse IR1, the scan section 2 transmits a first killer pulse Gk1 in such a manner that a gradient magnetic field for causing transverse or lateral magnetization of each spin inverted by the first inversion recovery pulse IR1 to disappear is generated as shown in FIG. 3.

As shown in FIG. 3, after transmission of the fast recovery pulse FR at every repetition time TR in the imaging sequence IS and before the transmission of the second inversion recovery pulse IR2, the scan section 2 transmits a second killer pulse Gk2 in such a manner that a gradient magnetic field for causing lateral magnetization of each spin at which the fast recovery pulse FR is transmitted, to disappear is generated.

As shown in FIG. 3, after the transmission of the second inversion recovery pulse IR2, the scan section 2 transmits a third killer pulse Gk3 in such a manner that a gradient magnetic field for causing lateral magnetization of each spin inverted by the second inversion recovery pulse IR2 to disappear is generated.

The details of the respective imaging pulses in the imaging sequence IS will be explained sequentially.

As shown in FIG. 3, a first inversion recovery pulse IR1 is first transmitted.

Here, the first inversion recovery pulse IR1 is transmitted in such a manner that a spin faced in a z direction formed with a static magnetic field at a subject is rotated by 180° about an x direction orthogonal to the z direction and a y direction orthogonal to the z direction. That is, the first inversion recovery pulse IR1 at which a flip angle is 180° and the phase is placed in the x direction, is transmitted between a first point of time t1 and a second point of time t2 in such a manner that the spin faced in the z direction is flipped along a yz plane including the z direction and the y direction and a magnetization vector is inverted.

In the present embodiment, when the first inversion recovery pulse IR1 is transmitted, a gradient pulse Gs1 is transmitted as shown in FIG. 3 in the imaging sequence IS in such a manner that a second subject region R21 broader than a first subject region R11 at which an excitation pulse RF1i and a fast recovery pulse FR are transmitted, is brought to a slice selection region as shown in FIG. 4. The gradient pulse Gs1 is transmitted in a slice selection direction SS in such a manner that, for example, the second subject region R21 is brought to a slice selection width SL2 made about 1.5 times wider than a slice selection width SL1 at the transmission of a fast recovery pulse FR.

Next, a first killer pulse Gk1 is transmitted as shown in FIG. 3.

Here, the first killer pulse Gk1 is transmitted in such a manner that a gradient magnetic field for causing lateral magnetization of each spin inverted by the first inversion recovery pulse IR1 to disappear is generated. In the present embodiment, the first killer pulse Gk1 is transmitted within an inversion time TI subsequent to the transmission of the first inversion recovery pulse IR1 and immediately after the completion of the transmission of the first inversion recovery pulse IR1.

Next, an excitation pulse RF1i is transmitted as shown in FIG. 3.

Here, the excitation pulse RF1i is transmitted in such a manner that a center point of time t2i at which the excitation pulse RF1i is transmitted, corresponds after the predetermined inversion time TI at which vertical or longitudinal magnetization is recovered by longitudinal relaxation has elapsed since a center point of time t1c at which the first inversion recovery pulse IR1 has been transmitted, thereby rotating the spin 90° about the x direction. That is, a magnetization vector faced in the direction opposite to the direction of a static magnetic field and brought to negative longitudinal magnetization becomes positive in a short longitudinal relaxation time T1 and remains negative in a long relaxation time during the inversion time TI, by flipping the spin by the first inversion recovery pulse IR1. Thereafter, an excitation pulse RF1i whose flip angle is 90° and whose phase is in the x direction, is transmitted between a third point of time t3 and a fourth point of time t4 in such a manner that the magnetization vector of the spin is flipped along a yz plane to assume a 90°-tilted state.

In the present embodiment, upon transmission of the excitation pulse RF1i, a gradient pulse Gs2 is transmitted in a slice selection direction as shown in FIG. 3 in such a manner that a first subject region R11 narrower than the second and third subject regions R21 and R31 at which the first inversion recovery pulse IR1, the plurality of first refocus pulses RF2i and RF3i, the second refocus pulse RF4i and the second inversion recovery pulse IR2 are transmitted, is brought to a slice selection region in the imaging sequence IS as shown in FIG. 4, thereby forming a gradient magnetic field.

Next, a plurality of first refocus pulses RF2i and RF3i are transmitted as shown in FIG. 3.

Here, the first refocus pulse RF2i is transmitted in such a manner that a center point of time t3c at which the first refocus pulse RF2i is transmitted, corresponds after a first time T10 has elapsed since the center point of time t2i at which the excitation pulse RF1i has been sent. The first refocus pulse RF3i is transmitted in such a manner that a center point of time t4c at which the first refocus pulse RF3i is transmitted corresponds, after a second time T20 (echo spacing (ESP)) equal to twice the first time T10 has elapsed since the center point of time t3c at which the first refocus pulse RF2i has been transmitted. Described specifically, these plural first refocus pulses RF2i and RF3i are respectively transmitted in such a manner that the spin at which the excitation pulse RF1i is transmitted, is dephased with the elapse of time and thereafter rotated by 180° about the y direction. That is, the plural first refocus pulses RF2i and RF3i whose flip angles are 180° and whose phases are placed in the y direction, are respectively transmitted between a fifth point of time t5 and a sixth point of time t6 and between a seventh point of time t7 and an eighth point of time t8 in such a manner that the magnetization vector of the spin flipped by the excitation pulse RF1i is flipped along an xz plane including the z direction formed with the static magnetic field and the x direction orthogonal to the z and y directions and thereby inverted, thereby allowing the spin to reconverge and restoring phase coherence.

In the present embodiment, a plurality of gradient pulses Gs3 and Gs4 are respectively transmitted in the slice selection direction as shown in FIG. 3 in such a manner that when the plural first refocus pulses RF2i and RF3i are sequentially transmitted with the echo spacing ESP left therebetween, a third subject region R31, which is broader than the first subject region R11 at which the excitation pulse RF1i and the fast recovery pulse FR are transmitted, and similar to the second subject region R21 selected upon transmission of the first inversion recovery pulse IR1, is brought to a slice selection region in the imaging sequence IS as shown in FIG. 4, thereby forming gradient magnetic fields. When the plural gradient pulses Gs3 and Gs4 are respectively transmitted, a pair of crusher gradient pulses is transmitted with being added before and after the first refocus pulses RF2i and RF3i so as to eliminate FID (Free Induction Decay) signals produced by the plural first refocus pulses RF2i and RF3i.

Incidentally, the plural gradient pulses Gs3 and Gs4 transmitted upon sequentially transmitting the plural first refocus pulses RF2i and RF3i may preferably be transmitted in such a manner that when fluid such as blood flows into a slice having a slice surface selected as an imaging area along a slice selection direction SS orthogonal to the slice surface as shown in FIG. 4, the third subject region R31 broader than the first subject region R11 is brought to a slice selection region. On the other hand, when the fluid such as blood flows into the slice along the slice surface extending in the direction orthogonal to the slice selection direction SS and selected as the imaging area, the plural gradient pulses Gs3 and Gs4 may preferably be transmitted in such a manner that the same region as the first subject region R11 is brought to the slice selection region.

Further, after the plural first refocus pulses RF2i and RF3i have been transmitted, gradient pulses (not shown) are transmitted in phase encode and frequency encode directions respectively in such a manner that gradient magnetic fields are formed corresponding to the three-dimensional fast spin echo method, and magnetic resonance signals are sequentially sampled corresponding to the point of time at which the spin has reconverged as mentioned above, whereby imaging data about the first subject region R11 are obtained.

Next, a second refocus pulse RF4i is transmitted as shown in FIG. 3.

Here, the second refocus pulse RF4i is transmitted in such a manner that a center point of time t5c at which the second refocus pulse RF4i is transmitted corresponds, after a second time T20 has elapsed since the center point of time t4c at which the first refocus pulse RF3i has been sent. Described specifically, the second refocus pulse RF4i is transmitted in such a manner that a spin at which each of the plural first refocus pulses RF2i and RF3i has been transmitted, is rotated by 180° about the y direction. That is, the second refocus pulse RF4i whose flip angle is 180° and whose phase is placed in the y direction, is transmitted between an eighth point of time t8 and a ninth point of time t9 in such a manner that after the spin flipped by each of the plural first refocus pulses RF2i and RF3i has been dephased, a magnetization vector of the spin flipped by each of the plural first refocus pulses RF2i and RF3i is flipped along the xz plane so as to be inverted, thereby allowing the spin to reconverge and restoring phase coherence.

In the present embodiment, a gradient pulse Gs5 is transmitted in the slice selection direction as shown in FIG. 3 in such a manner that when the second refocus pulse RF4i is transmitted, a third subject region R31, which is broader than the first subject region R11 at which the excitation pulse RF1i and the fast recovery pulse FR are transmitted, and similar to the second subject region R21 slice-selected upon transmission of the first inversion recovery pulse IR1, is brought to a slice selection region in the imaging sequence IS as shown in FIG. 4, thereby forming a gradient magnetic field. When the gradient pulse Gs5 is transmitted, a crusher gradient pulse is transmitted with being added before and after the second refocus pulse RF4i so as to eliminate an FID signal produced by the second refocus pulse RF4i.

Next, a fast recovery pulse FR is transmitted as shown in FIG. 3.

Here, the fast recovery pulse FR is transmitted in such a manner that a center point of time t6c at which the fast recovery pulse FR is transmitted, corresponds after the first time T10 has elapsed since the center point of time t5c at which the second refocus pulse RF4i has been transmitted. Described specifically, the fast recovery pulse FR is transmitted in such a manner that the spin at which the second refocus pulse RF4i has been transmitted, is rotated by −90° about the x direction after its reconvergence. That is, the fast recovery pulse FR whose flip angle is 90° and whose phase is placed in the x direction is transmitted between a tenth point of time t10 and an eleventh point of time t11 in such a manner that a magnetization vector of the spin flipped by the second refocus pulse RF4i is flipped along the yz plane so as to recover longitudinal magnetization.

In the present embodiment, when the fast recovery pulse FR is transmitted, a gradient pulse Gs6 is transmitted in the slice selection direction as shown in FIG. 3 in such a manner that the first subject region R11 which is a region narrower than the region 21 at which the first inversion recovery pulse IR1, the plural first refocus pulses RF2i and RF3i, the second refocus pulse RF4i and the second inversion recovery pulse IR2 are transmitted and which is similar to that at the transmission of the excitation pulse RF1i, is brought to a slice selection region in the imaging sequence IS, thereby forming a gradient magnetic field as shown in FIG. 4.

Next, a second killer pulse Gk2 is transmitted as shown in FIG. 3.

Here, the second killer pulse Gk2 is transmitted in such a manner that a gradient magnetic field for causing lateral magnetization of the spin at which the fast recovery pulse FR is transmitted, to disappear is generated. In the present embodiment, the second killer pulse Gk2 is transmitted immediately after the completion of transmission of the fast recovery pulse FR.

Next, a second inversion recovery pulse IR2 is transmitted as shown in FIG. 3.

Here, immediately after the transmission of the second killer pulse Gk2 has been completed and after a third time T30 has elapsed since the center point of time t6c at which the fast recovery pulse FR has been transmitted, the second inversion recovery pulse IR2 is transmitted in such a manner that a center point of time t7c at which the second inversion recovery pulse IR2 is transmitted, corresponds, thereby rotating the spin at which the fast recovery pulse FR is transmitted, by −180° about the y direction. That is, the second inversion recovery pulse IR2 whose flip angle is 180° and whose phase is placed in the y direction is transmitted between a twelfth point of time t12 and a thirteenth point of time t13 in such a manner that a magnetization vector of the spin flipped by the fast recovery pulse FR is flipped along the xz plane so as to be inverted.

In the present embodiment, when the second inversion recovery pulse IR2 is transmitted, a gradient pulse Gs7 is transmitted in the slice selection direction as shown in FIG. 3 in such a manner that the second subject region R12 which is a region broader than the first subject region R11 at which the excitation pulse RF1i and the fast recovery pulse FR are transmitted and which is similar to that at the transmission of the first inversion recovery pulse IR1, is brought to a slice selection region in the imaging sequence IS, thereby forming a gradient magnetic field, as shown in FIG. 4.

Next, a third killer pulse Gk3 is transmitted as shown in FIG. 3.

Here, the third killer pulse Gk3 is transmitted in such a manner that a gradient magnetic field for causing lateral magnetization of the spin inverted by the second inversion recovery pulse IR2 to disappear is generated. In the present embodiment, the third killer pulse Gk3 is transmitted immediately after the completion of transmission of the second inversion recovery pulse IR2.

Thus, magnetic resonance signals are acquired as imaging data by executing the imaging sequence IS.

Next, it is determined whether all imaging data corresponding to k space are acquired as shown in FIG. 2 (S22).

Here, the controller 30 determines whether all imaging data corresponding to each matrix defining the k space are acquired.

When all the imaging data corresponding to the k space are not acquired (No), the imaging sequence IS is sequentially executed again as shown in FIG. 2 (S21). That is, the execution (S21) of the imaging sequence IS is repeatedly made every repetition time TR, thereby acquiring imaging data until the k space is all filled up.

On the other hand, when all the imaging data are acquired so as to correspond to the k space (Yes), the generation of an image is done as shown in FIG. 2 (S31).

Here, the scan section 2 sets the imaging data obtained by executing the imaging sequence IS as raw data, and the data processor 31 reconstructs each image about the first subject region of the subject SU.

Next, the display of the image is done as shown in FIG. 2 (S41).

Here, the display unit 33 receives the data about the image of the subject SU from the data processor 31 and displays the same on its screen.

In the present embodiment as described above, the first inversion recovery pulse IR1 is transmitted so as to invert each spin in the second subject region R21 including the first subject region R11 and broader than the first subject region R11 at the subject before the execution of the pulse sequence corresponding to the fast spin echo method at every repetition time TR in the imaging sequence IS. Upon execution of the pulse sequence corresponding to the fast spin echo method in the imaging sequence IS, the excitation pulse RF1i is transmitted so as to selectively the spins in the first subject region R11 at the subject, and the plurality of first refocus pulses RF2i and RF3i are transmitted so as to allow each spin of the third subject region R31 including the first subject region R11 to reconverge at the subject at which the excitation pulse RF1i is transmitted. After the execution of the pulse sequence corresponding to the fast spin echo method at every repetition time TR in the imaging sequence IS, the second refocus pulse RF4i is transmitted so as to allow each spin in the third subject region R31 including the first subject region R11 to reconverge at the subject subjected to the pulse sequence corresponding to the fast spin echo method. The fast recovery pulse FR is transmitted so as to selectively recover the spins of the first subject region R11 at the subject at which the second refocus pulse RF4i has been transmitted. Thereafter, the second inversion recovery pulse IR2 is transmitted so as to invert each spin in the second subject region R21 at the subject at which the fast recovery pulse FR has been transmitted.

Therefore, in the present embodiment, the first inversion recovery pulse IR1 is transmitted so as to select the slice broader than the excitation pulse RF1i at the pulse sequence based on the fast spin echo method upon transmission of the first inversion recovery pulse IR1. Thus, the inversion recovery pulse is applied to the fluid that flows from the outside to inside of the slice. Upon transmission of the second refocus pulse RF4i after execution of the pulse sequence corresponding to the fast spin echo method in the imaging sequence IS, the second refocus pulse RF4i is transmitted so as to select the slice broader than the excitation pulse RF1i transmitted in the pulse sequence based on the fast spin echo method. Therefore, each spin of a flow running through the neighborhood of the boundary of the slice is refocused. Thus, in the present embodiment, the fluid that flows from outside the first subject region R11 can suitably be drawn or plotted upon photography of the first subject region R11 corresponding to the slice including the fluid at the subject. It is therefore possible to make it easy to generate each image having desired image quality and enhance the quality of the image.

Further, in the present embodiment, the fast recovery pulse FR and the second inversion recovery pulse IR2 are transmitted after the execution of the pulse sequence based on the fast spin echo method. Therefore, a waiting time taken to recover the magnetization of the spin of fluid such as blood long in relaxation time T1 can greatly be shortened, thereby making it possible to enhance imaging or photography efficiency. Particularly when imaging is performed in the FBI method by applying the STIR method to the fast spin echo method for the purpose of fat control, the number of times that the magnetic resonance signals are acquired by a cardiac synchronization method, can be increased. This is therefore effective in executing the imaging.

In the present embodiment, before the execution of the pulse sequence corresponding to the fast spin echo method at every repetition time TR in the imaging sequence IS and after the transmission of the first inversion recovery pulse IR1, the first killer pulse Gk1 is transmitted in such a manner that the gradient magnetic field for causing the lateral magnetization of the spin inverted by the first inversion recovery pulse IR1 to disappear is generated. After the transmission of the fast recovery pulse FR at every repetition time TR in the imaging sequence IS and before the transmission of the second inversion recovery pulse IR2, the second killer pulse Gk2 is transmitted in such a manner that the gradient magnetic field for causing the lateral magnetization of the spin at which the fast recovery pulse FR is transmitted, to disappear, is generated. Along with it, the third killer pulse Gk3 is transmitted after the transmission of the second inversion recovery pulse IR2 in such a manner that the gradient magnetic field for causing the lateral magnetization of the spin inverted by the second inversion recovery pulse IR2 to disappear is generated. It is therefore possible to further enhance image quality.

### Second Embodiment

A second embodiment according to the invention will be explained below.

The present embodiment is different from the first embodiment in terms of a scan effected on an imaging area of a subject SU. The present embodiment is similar to the first embodiment except for it. Explanations of dual spots or items will therefore be omitted.

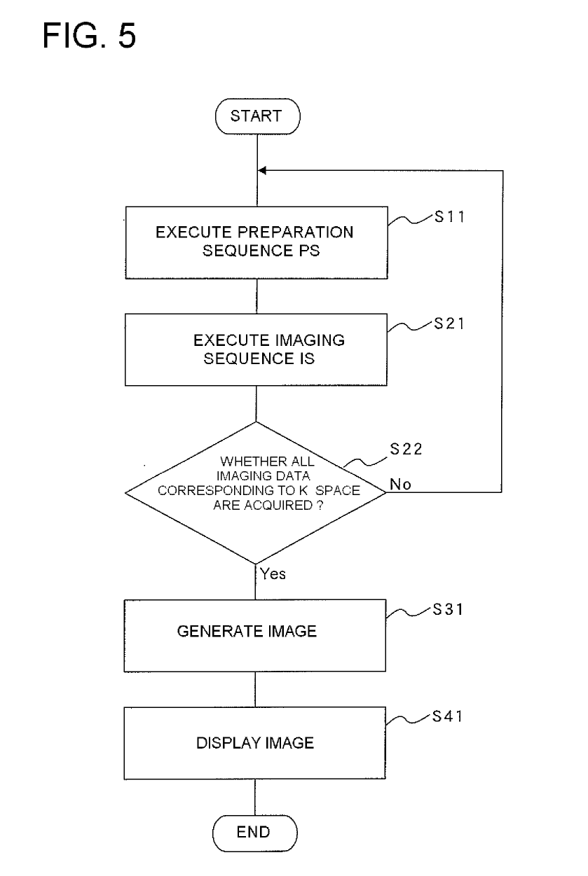

FIG. 5 is a flowchart showing operation at the execution of the scan on the imaging area of the subject SU in the second embodiment according to the invention.

As shown in FIG. 5, a preparation sequence PS is first executed (S11).

Here, the scan section 2 performs the preparation sequence PS.

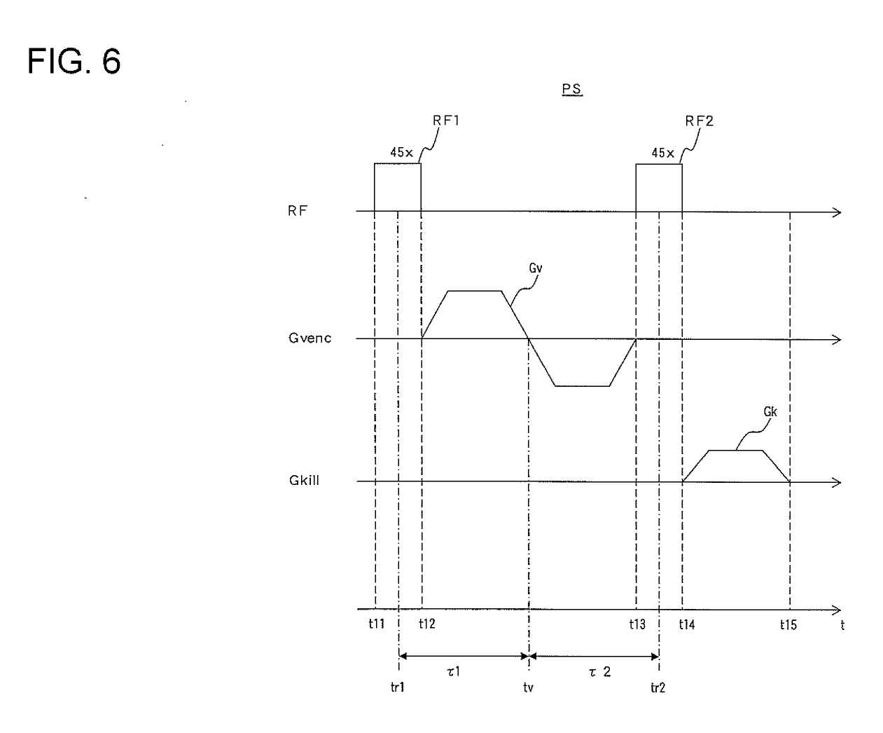

FIG. 6 is a pulse sequence diagram showing the preparation sequence PS employed in the second embodiment according to the invention.

In FIG. 6, RF indicates a time base on which RF pulses are transmitted, Gvenc indicates a time base on which velocity encode gradient pulses are transmitted, and Gkill indicates a time base on which killer pulses area transmitted. At their RF, Gvenc and Gkill, the horizontal axis indicates a time t, and the vertical axis indicates a pulse intensity, respectively. Here, each of Gvenc and Gkill is the time base on which the gradient pulses are transmitted and is a time base in at least one of a slice selection direction, a phase encode direction and a frequency encode direction.

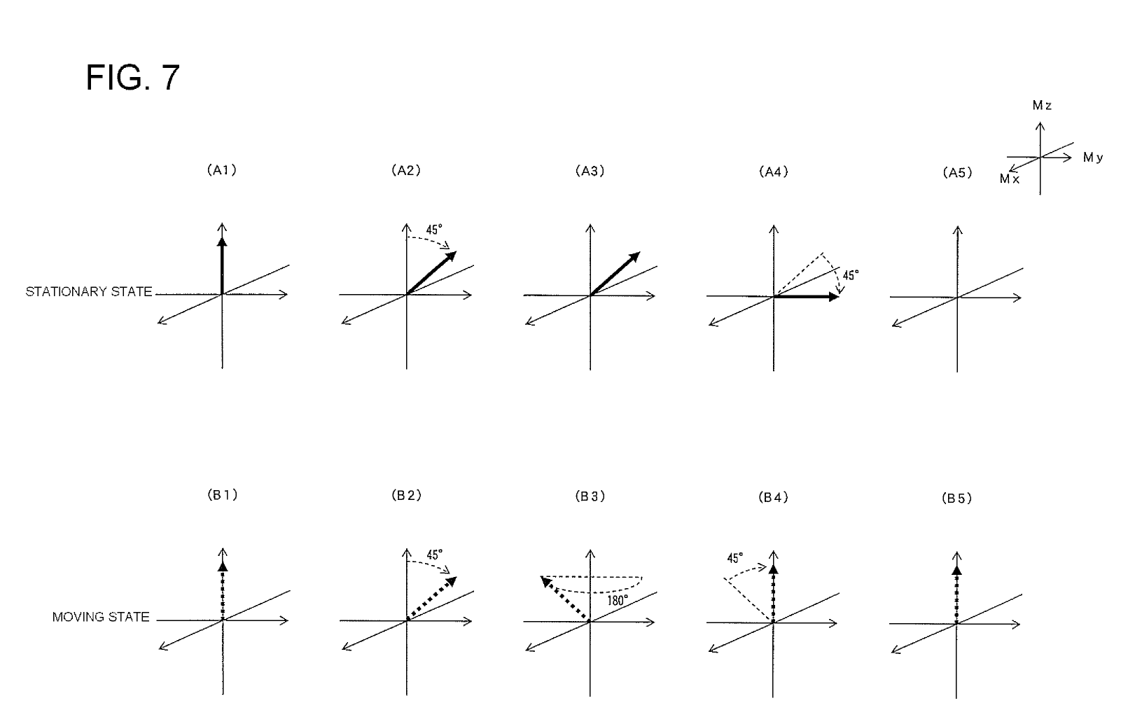

FIG. 7 is a vector diagram showing the behaviors of spins of a subject SU when the preparation sequence PS is carried out in the second embodiment according to the invention.

In FIG. 7, (A1), (A2), (A3), (A4) and (A5) are respectively diagrams showing sequentially behaviors about a spin S1 having a first velocity V1 in time sequence order at the subject SU. Here, they show the behaviors about the spin S1 zero in the first velocity V1 and placed in a stationary state. On the other hand, (B1), (B2), (B3), (B4) and (B5) in FIG. 7 are respectively diagrams showing sequentially behaviors about a spin S2 moved at a second velocity V2 faster than the first velocity V1 in time sequence order at the subject SU.

In FIG. 7, (A1) and (B1) respectively show states indicated by the spins S1 and S2 at a first point of time t11 in the pulse sequence diagram shown in FIG. 6. (A2) and (B2) respectively show states indicated by the spins S1 and S2 at a second point of time t12 in the pulse sequence diagram shown in FIG. 6. (A3) and (B3) respectively show states indicated by the spins S1 and S2 at a third point of time t13 in the pulse sequence diagram shown in FIG. 6. (A4) and (B4) respectively show states indicated by the spins S1 and S2 at a fourth point of time t14 in the pulse sequence diagram shown in FIG. 6. (A5) and (B5) respectively show states indicated by the spins S1 and S2 at a fifth point of time t15 in the pulse sequence diagram shown in FIG. 6.

Upon execution of the preparation sequence PS as shown in FIG. 6, the scan section 2 sequentially transmits a first RF pulse RF1, a velocity encode gradient pulse Gv, a second RF pulse RF2 and a killer pulse Gk to the subject SU as preparation pulses.

Here, the first RF pulse RF1, the velocity encode gradient pulse Gv and the second RF pulse RF2 are sequentially transmitted to the subject SU in such a manner that a first time interval τ1 defined between a center point of time tr1 of a time for transmission of the first RF pulse RF1 and a center point of time tv of a time for transmission of the velocity encode gradient pulse Gv, and a second time interval τ2 defined between the center point of time tv of the time for transmission of the velocity encode gradient pulse Gv and a center point of time tr2 of a time for transmission of the second RF pulse RF2 become identical to each other. That is, the velocity encode gradient pulse Gv is transmitted during the transmission of the first RF pulse RF1 and the second RF pulse RF2. Thereafter, the killer pulse Gk is further transmitted.

The preparation pulses in the preparation sequence PS will be explained sequentially.

The first RF pulse RF1 is transmitted to the subject SU as shown in FIG. 6.

Here, as shown in FIG. 6, the scan section 2 transmits the first RF pulse RF1 corresponding to a rectangular pulse during a period from the first point of time t11 to the second point of time t12. In the present embodiment, magnetization vectors are faced in a static magnetic field direction z at the subject SU as shown in FIGS. 7(A1) and 7(B1). The scan section 2 transmits the first RF pulse RF1 to the spins S1 and S2 of protons different in velocity from each other. As shown in FIGS. 7(A2) and 7(B2), the magnetization vectors of the spins S1 and S2 are flipped along a yz plane.

Described specifically, as shown in FIGS. 7(A1) and 7(B1), the first RF pulse RF1 whose flip angle is 45° and whose phase is in an x direction, is transmitted to the spins S1 and S2 which are M0 in longitudinal magnetization and zero in lateral magnetization. As shown in FIGS. 7(A2) and 7(B2), the magnetization vectors of the spins S1 and S2 are tilted from a 0° direction to a 45° direction as viewed on the yz plane.

Next, as shown in FIG. 6, the velocity encode gradient pulse Gv is transmitted to the subject SU.

Here, as shown in FIG. 6, the scan section 2 transmits the velocity encode gradient pulse Gv during a period from the second point of time t12 to the third point of time t13. In the present embodiment, the scan section 2 transmits the velocity encode gradient pulse Gv as a Bipolar pulse having integral values opposite in polarity to each other and identical in time on the time base about the center point of time tv at which the velocity encode gradient pulse Gv is transmitted. As to the spins S1 and S2 flipped by the first RF pulse RF1 as shown in FIGS. 7(A3) and 7(B3), the phase of the spin S1 having the first velocity V1 and the phase of the spin S2 having the second velocity V2 faster than the first velocity V1 are shifted to each other.

Described specifically, the velocity encode gradient pulse Gv is transmitted in such a manner that as shown in FIGS. 7(A3) and 7(B3), the phase of the spin S1 of the proton zero in the first velocity V1 and placed in the stationary state and the phase of the spin S2 of the proton placed in a moving state, which is moved at the second velocity V2 faster than the first velocity V1, are shifted 180° from each other. That is, as to the spin S1 of the proton placed in the stationary state, the direction of the magnetization vector of the spin S1 is kept unchanged by the transmission of the velocity encode gradient pulse Gv as shown in FIG. 7(A3). On the other hand, as to the spin S2 of the proton placed in the moving state, as shown in FIG. 7(B3), the magnetization vector of the spin S2 is rotated at an angle of 180° along the xy plane by the transmission of the velocity encode gradient pulse Gv, and the magnetization vector is changed so as to be faced from a 45° direction to −45° direction as viewed on the yz plane.

Next, the second RF pulse RF2 is transmitted as shown in FIG. 6.

Here, as shown in FIG. 6, the scan section 2 transmits the second RF pulse RF2 corresponding to a rectangular pulse during a period from the third point of time t13 to the fourth point of time t14. As shown in FIGS. 7(A4) and 7(B4), the spins S1 and S2 whose phases are shifted by the velocity encode gradient pulse Gv are flipped along the yz plane.

Described specifically, the second RF pulse RF2 whose flip angle is 45° and whose phase is in the x direction is transmitted to tilt the magnetization vector of the spin S1 placed in the stationary state from a 45° direction to a 90° direction as viewed on the yz plane as shown in FIG. 7(A4) and tilt the magnetization vector of the spin S2 placed in the moving state from a −45° direction to a 0° direction as viewed on the yz plane as shown in FIG. 7(B4).

Incidentally, when the angle at which the phase is shifted by the velocity encode gradient pulse Gv is assumed to be θ, longitudinal magnetization Mz and lateral magnetization Mxy are expressed in the following equations (1) and (2):

$$\begin{matrix}\text{[Equation 1]} & \\ Mz = \frac{( 1 - cos θ )}{2} & ( 1 ) \\ \text{[Equation 2]} & \\ Mxy = \sqrt{1 - \frac{{( 1 - cos θ )}^{2}}{4}} & ( 2 )\end{matrix}$$

Next, the killer pulse Gk is transmitted to the subject SU as shown in FIG. 6.

Here, as shown in FIG. 6, the scan section 2 transmits the killer pulse Gk during a period from the fourth point of time t14 to the fifth point of time t15. As shown in FIGS. 7(A5) and 7(B5), the lateral magnetization of each of the spins S1 and S2 flipped by the second RF pulse RF2 is caused to disappear.

That is, as shown in FIG. 7(A5), the killer pulse Gk is transmitted to cause magnetization vector of the spin S1 faced in the 90° direction and placed in the stationary state to disappear by its phase dispersion.

Next, as shown in FIG. 5, the imaging sequence IS is executed (S21).

Here, the scan section 2 executes the imaging sequence IS in a manner similar to the first embodiment to acquire magnetic resonance signals as imaging data.

Next, as shown in FIG. 5, it is determined whether all imaging data corresponding to k space are acquired (S22).

Here, the controller 30 determines whether all the imaging data corresponding to the k space are acquired.

When it is determined that all the imaging data corresponding to the k space are not acquired (No), the execution of the preparation sequence PS (S11) and the execution of the imaging sequence IS (S21) are sequentially made again as shown in FIG. 5. That is, the execution of the preparation sequence PS (S11) and the execution of the imaging sequence IS (S21) are repeatedly made to acquire the imaging data until the k space is all filled up.

On the other hand, when it is determined that all the imaging data corresponding to the k space are acquired (Yes), the generation of an image is done (S31).

Here, the scan section 2 sets the imaging data obtained by execution of the imaging sequence IS as raw data, and the data processor 31 reconstructs an image about the subject SU.

In the present embodiment, as described above, the spin held in the moving state has large longitudinal magnetization and the difference between the longitudinal magnetization of the spin held in the moving state and the longitudinal magnetization of the spin held in the stationary state is large. Therefore, an image in which the spin held in the moving state has been emphasized is generated.

Next, the image is displayed as shown in FIG. 5 (S41).

Here, the display unit 33 receives data about each image of the subject SU from the data processor 31 and displays the image on its display screen.

In the present embodiment as described above, the scan section 2 executes the imaging sequence IS and executes the preparation sequence PS for transmitting the preparation pulses to the subject SU before the execution of the imaging sequence IS. The scan section 2 transmits, as the preparation pulses, the first RF pulse RF1 for flipping each spin faced in the static magnetic field direction z along the yz plane at the subject SU, the velocity encode gradient pulse Gv for shifting the phase of the spin S1 held in the stop state and the phase of the spin S2 held in the moving state, both corresponding to the spins flipped by the first RF pulse RF1, and the second RF pulse RF2 for flipping the spins S1 and S2 whose phases are shifted by the velocity encode gradient pulse Gv, along the yz plane to the subject SU sequentially. Here, the first RF pulse RF1, the velocity encode gradient pulse Gv and the second RF pulse RF2 are sequentially transmitted to the subject SU in such a manner that the first time interval τ1 defined between the center point of time tr1 of the time for transmission of the first RF pulse RF1 and the center point of time tv of the time for transmission of the velocity encode gradient pulse Gv, and the second time interval τ2 defined between the center point of time tv of the time for transmission of the velocity encode gradient pulse Gv and the center point of time tr2 of the time for transmission of the second RF pulse RF2 become identical to each other. Thereafter, the killer pulse Gk is further transmitted to cause the lateral magnetization of each spin flipped by the second RF pulse RF2 to disappear.

Therefore, the present embodiment is capable of obtaining each image in which a portion moved at a predetermined moving velocity is emphasized in the imaging area of the subject SU as described above. Since the time required to apply each of the preparation pulses is short, the present embodiment can be made available for various applications. Since each of magnetic resonance signals from arteries fast in flow rate such as the abdominal aorta, arteria iliaca communis, femoral artery and the like can be obtained with a signal intensity high as compared with veins, cerebral fluid, urine or the like, a high contrast image can be obtained according to the moving velocity. Thus, the present embodiment is capable of enhancing general versatility without using a contrast agent in addition to the effects of the first embodiment and further improving image quality.

Incidentally, the magnetic resonance imaging apparatus 1 of the above embodiment is equivalent to the magnetic resonance imaging apparatus of the invention. The scan section 2 of the above embodiment corresponds to the scan section of the invention. The data processor 31 of the above embodiment corresponds to the image generator of the invention. The display unit 33 of the above embodiment corresponds to the display unit of the invention.

Upon implementation of the invention, the invention is not limited to the above-described embodiments, and various modifications can be adopted.

Although the above embodiment has shown, for example, the case in which upon execution of the imaging sequence IS, the gradient magnetic field is transmitted in the slice selection direction so as to select the second subject region R21 or third subject region R31 including the first subject region R11 and wider than the first subject region R11 at the subject when the first inversion recovery pulse IR1, the plural first refocus pulses RF2i and RF3i, the second refocus pulse RF4i, the fast recovery pulse FR and the second inversion recovery pulse IR2 are transmitted, the invention is not limited to it. For example, the respective RF pulses may be transmitted so as to cause a nuclear magnetic resonance phenomenon with respect to a region wider than the first subject region R11 at the subject without transmitting the gradient pulse to the subject so as to form the gradient magnetic field in the above slice selection direction. Particularly when the first inversion recovery pulse IR1, the plural first refocus pulses RF2i and RF3i, the second refocus pulse RF4i and the second inversion recovery pulse IR2 are transmitted, the gradient magnetic field in the slide selection direction may not preferably be transmitted to the subject simultaneously. This is because when done in this way, the first inversion recovery pulse IR1, the plural first refocus pulses RF2i and RF3i, the second refocus pulse RF4i and the second inversion recovery pulse IR2 can be transmitted to spins of fluid flowing from outside with respect to each slice excited by an excitation pulse RF₁ and fluid existing in the vicinity of a slice's boundary, and hence the above fluid can be extracted more accurately with respect to an image obtained by performing image reconstruction about the slice.

Although the above embodiment has shown, for example, the case in which upon execution of the imaging sequence IS, the two RF pulses are transmitted as the plural first refocus pulses, the invention is not limited to it. For example, the number of RF pulses may be three or more. Incidentally, the number of inversion pulses corresponding to the sum of the plural first refocus pulses and the second refocus pulse may preferably be even upon execution of the imaging sequence IS. Therefore, when the sum of the plurality of first focus pulses and the second refocus pulse becomes odd, it is preferable that one of the plural first refocus pulse is used as a dummy pulse and magnetic resonance signals are not received at ETL at which the dummy pulse is transmitted.

Although the above embodiment has explained the case in which the rectangular pulses are transmitted as the RF pulses such as the inversion pulses, refocus pulse and the like since they are wide in frequency band and effective in nonuniformity of the static magnetic field, the invention is not limited to it.

Upon transmitting the RF pulses as the preparation pulses in the preparation sequence PS, no limitations are imposed on the above case. For example, no limitations are applied to the above numerical values of flip angles. In this case, the gradient magnetic field may be transmitted in the slice selection direction so as to select a specific slice. A crusher gradient pulse may be transmitted so as to form a crusher gradient magnetic field on an arbitrary axis.

Upon transmitting the velocity encode gradient pulse as the preparation pulse in the preparation sequence PS, it may be transmitted to a plurality of arbitrary axes. The velocity encode gradient pulse may be transmitted in an arbitrary area or may be transmitted in accordance with the arbitrary number of times.

The present embodiment may be applied to the case in which the above scan is performed in sync with respiratory movements of a subject. Here, it is preferable to execute a scan so as to be synchronized with expiration or the state of expiration, for example.

During diastole and cardiac systole, images for a first subject region are generated by executing scans in the imaging sequence IS on the basis of the FBI method, and an MRA image related to the first subject region may be obtained using the value of the difference between the images. The preparation sequence PS may be applied to it. That is, preparation pulses are applied in the preparations sequence PS so as to change the signal intensity of magnetization of a given specific flow rate, followed by acquisition of imaging data in the imaging sequence IS, thereby generating a first image. Further, preparation pulses are applied in the preparation sequence PS so as to change the signal intensity of magnetization of a different specific flow rate, followed by acquisition of imaging data in the imaging sequence IS, thereby generating a second image. Thereafter, difference processing may be performed between the first and second images to generate an MRA image. In addition to it, preparation pulses are applied in the preparation sequence PS so as to change the signal intensity of magnetization of a given specific flow rate, followed by acquisition of imaging data in the imaging sequence IS, thereby generating a first image. Further, imaging data are acquired in the imaging sequence IS without executing the preparation sequence PS, thereby generating a second image. Thereafter, difference processing may be performed between the first and second images to generate an MRA image.

The invention may be applied even to a case in which the signal intensity of magnetization of a specific flow rate is attenuated and the signal intensity of magnetization other than it is maintained, in addition to the case in which the signal intensity of magnetization of the specific flow rate is maintained and the signal intensity of magnetization other than it is attenuated.

Many widely different embodiments of the invention may be configured without departing from the spirit and the scope of the present invention. It should be understood that the present invention is not limited to the specific embodiments described in the specification, except as defined in the appended claims.

1. A magnetic resonance imaging apparatus comprising:
a scan device for repeatedly executing, every repetition time, an imaging sequence including a pulse sequence for sequentially transmitting an excitation pulse and a plurality of first refocus pulses to a subject including fluid, so as to correspond to a fast spin echo method in an imaging space formed with a static magnetic field, thereby obtaining magnetic resonance signals generated in a first subject region including the fluid at the subject every repetition time; and
an image generation device for generating images about the first subject region, based on the magnetic resonance signals obtained by executing the imaging sequence by the scan device,
wherein before execution of the pulse sequence corresponding to the fast spin echo method at the every time of repetition in the imaging sequence, the scan device transmits a first inversion recovery pulse so as to invert spins in a second subject region that includes the first subject region and is broader than the first subject region, at the subject.

2. The magnetic resonance imaging apparatus according to claim 1, wherein before execution of the pulse sequence corresponding to the fast spin echo method at the every repetition time in the imaging sequence and after the transmission of the first inversion recovery pulse, the scan device transmits a first killer pulse so as to generate a gradient magnetic field for causing lateral magnetization of the spins inverted by the first inversion recovery pulse to disappear.

3. The magnetic resonance imaging apparatus according to claim 1, wherein upon executing the pulse sequence corresponding to the fast spin echo method, the scan device transmits the excitation pulse so as to selectively excite the spins in the first subject region.

4. The magnetic resonance imaging apparatus according to claim 3, wherein upon executing the pulse sequence corresponding to the fast spin echo method, the scan device transmits the plurality of first refocus pulses so as to cause spins in a third subject region including the first subject region to reconverge at the subject after the transmission of the excitation pulse.

5. The magnetic resonance imaging apparatus according to claim 4, wherein after execution of the pulse sequence corresponding to the fast spin echo method at the every repetition time in the imaging sequence, the scan device transmits a second refocus pulse so as to cause the spins in the third subject region to reconverge, transmits a fast recovery pulse so as to selectively recover the spins in the first subject region included in the third subject region at which the second refocus pulse is transmitted, at the subject, and thereafter transmits a second inversion recovery pulse so as to invert the spins in the second subject region including the first subject region at which the fast recovery pulse is transmitted, at the subject.

6. The magnetic resonance imaging apparatus according to claim 5, wherein after the transmission of the fast recovery pulse at the every repetition time in the imaging sequence and before the transmission of the second inversion recovery pulse, the scan device transmits a second killer pulse so as to generate a gradient magnetic field for causing lateral magnetization of the spins at which the fast recovery pulse is transmitted, to disappear, and after the transmission of the second inversion recovery pulse, transmits a third killer pulse so as to generate a gradient magnetic field for causing lateral magnetization of the spins inverted by the second inversion recovery pulse to disappear.

7. The magnetic resonance imaging apparatus according to claim 5, wherein the scan device transmits the first inversion recovery pulse in such a manner that each spin faced in a static magnetic field direction formed with a static magnetic field at the subject is rotated by 180°,
transmits the excitation pulse in such a manner that the spin at which the first inversion recovery pulse is transmitted, is rotated by 90° about a second direction orthogonal to the static magnetic field direction and a first direction orthogonal to the static magnetic field direction,
transmits the plurality of first refocus pulses,
transmits the second refocus pulse,
transmits the fast recovery pulse in such a manner that each spin at which the second refocus pulse is transmitted, is rotated by −90° about the second direction, and
transmits the second inversion recovery pulse in such a manner that each spin at which the fast recovery pulse is transmitted, is rotated by −180°.

8. The magnetic resonance imaging apparatus according to claim 7, wherein the scan device transmits the first refocus pulses and the second refocus pulse in such a manner that each spin excited by the excitation pulse is rotated about the first direction.

9. The magnetic resonance imaging apparatus according to claim 1, wherein the scan device executes a preparation sequence for transmitting preparation pulses before execution of the imaging sequence so as to change a signal intensity of each magnetic resonance signal obtained by the imaging sequence according to the velocity of the fluid flowing through the subject.

10. The magnetic resonance imaging apparatus according to claim 1, wherein the scan device executes the imaging sequence in sync with cardiac motion of the subject.

11. A magnetic resonance imaging method comprising the steps of:
repeatedly executing, every repetition time, an imaging sequence including a pulse sequence for sequentially transmitting an excitation pulse and a plurality of first refocus pulses to a subject including fluid, so as to correspond to a fast spin echo method in an imaging space formed with a static magnetic field, thereby obtaining magnetic resonance signals generated in a first subject region including the fluid at the subject every repetition time;
thereafter generating images about the first subject region, based on the magnetic resonance signals obtained by executing the imaging sequence; and
before execution of the pulse sequence corresponding to the fast spin echo method at the every time of repetition in the imaging sequence, transmitting a first inversion recovery pulse so as to invert spins in a second subject region which includes the first subject region and is broader than the first subject region, at the subject.

12. The magnetic resonance imaging method according to claim 11, comprising a step of, before execution of the pulse sequence corresponding to the fast spin echo method at the every repetition time in the imaging sequence and after the transmission of the first inversion recovery pulse, transmitting a first killer pulse so as to generate a gradient magnetic field for causing lateral magnetization of the spins inverted by the first inversion recovery pulse to disappear.

13. The magnetic resonance imaging method according to claim 11, comprising a step of, upon executing the pulse sequence corresponding to the fast spin echo method, transmitting the excitation pulse so as to selectively excite the spins in the first subject region.

14. The magnetic resonance imaging method according to claim 13, comprising a step of, upon executing the pulse sequence corresponding to the fast spin echo method, transmitting the plurality of first refocus pulses so as to cause spins in a third subject region including the first subject region to reconverge at the subject after the transmission of the excitation pulse.

15. The magnetic resonance imaging method according to claim 14, comprising a step of, after execution of the pulse sequence corresponding to the fast spin echo method at the every repetition time in the imaging sequence, transmitting a second refocus pulse so as to cause the spins in the third subject region to reconverge, transmitting a fast recovery pulse so as to selectively recover the spins in the first subject region included in the third subject region at which the second refocus pulse is transmitted, at the subject, and thereafter transmitting a second inversion recovery pulse so as to invert the spins in the second subject region including the first subject region at which the fast recovery pulse is transmitted, at the subject.

16. The magnetic resonance imaging method according to claim 15, comprising a step of, after the transmission of the fast recovery pulse at the every repetition time in the imaging sequence and before the transmission of the second inversion recovery pulse, transmitting a second killer pulse so as to generate a gradient magnetic field for causing lateral magnetization of the spins at which the fast recovery pulse is transmitted, to disappear, and after the transmission of the second inversion recovery pulse, transmitting a third killer pulse so as to generate a gradient magnetic field for causing lateral magnetization of the spins inverted by the second inversion recovery pulse to disappear.

17. The magnetic resonance imaging method according to claim 15, comprising steps of:
transmitting the first inversion recovery pulse in such a manner that each spin faced in a static magnetic field direction formed with a static magnetic field at the subject is rotated by 180°,
transmitting the excitation pulse in such a manner that the spin at which the first inversion recovery pulse is transmitted, is rotated by 90° about a second direction orthogonal to the static magnetic field direction and a first direction orthogonal to the static magnetic field direction,
transmitting the plurality of first refocus pulses,
transmitting the second refocus pulse,
transmitting the fast recovery pulse in such a manner that each spin at which the second refocus pulse is transmitted, is rotated by −90° about the second direction, and
transmitting the second inversion recovery pulse in such a manner that each spin at which the fast recovery pulse is transmitted, is rotated by −180°.

18. The magnetic resonance imaging method according to claim 17, comprising a step of transmitting the first refocus pulses and the second refocus pulse in such a manner that each spin excited by the excitation pulse is rotated about the first direction.

19. The magnetic resonance imaging method according to claim 11, comprising a step of executing a preparation sequence for transmitting preparation pulses before execution of the imaging sequence so as to change a signal intensity of each magnetic resonance signal obtained by the imaging sequence according to the velocity of the fluid flowing through the subject.

20. The magnetic resonance imaging method according to claim 11, comprising a step of executing the imaging sequence in sync with cardiac motion of the subject.
